(19) United States
(12) Patent Application Publication
(10) Pub. No.: US 2020/0068745 A1
(43) Pub. Date: Feb. 27, 2020

(54) HEAT DISSIPATION STRUCTURE OF ELECTRONIC DEVICE

(71) Applicant: ASIA VITAL COMPONENTS CO., LTD., NewTaipei City (TW)

(72) Inventors: Sheng-Huang Lin, New Taipei City (TW); Yen-Lin Chu, New Taipei City (TW)

(21) Appl. No.: 16/108,099

(22) Filed: Aug. 22, 2018

(51) Int. Cl. H05K 7/20; F28D 15/04

(52) U.S. Cl. CPC H05K 7/20336; F28D 15/04; G06F 1/20; H05K 7/20154; H05K 7/20172

(57) ABSTRACT

A heat dissipation structure of electronic device includes a main body having a first heat pipe set and a second heat pipe set. The first heat pipe set includes at least one first heat pipe normal to the main body. A first thermal module and a first fan are disposed on the first heat pipe. The second heat pipe set includes at least one second heat pipe having a first section normal to the main body and a second section extending from the first section in parallel to the main body. A second thermal module and a second fan are disposed on the second section. The first fan creates a first airflow flowing through the first and second thermal modules in a first direction. The second fan creates a second airflow flowing through the second thermal module in a second direction.

### BACKGROUND OF THE INVENTION

### 1. Field of the Invention

The present invention relates generally to heat dissipation field, and more particularly to a heat dissipation structure of electronic device.

### 2. Description of the Related Art

In operation, many internal components of a computer will generate a great amount of heat. Therefore, a good heat dissipation system is a major key factor determining the operation performance and reliability of the computer. Among all the heat generation components, the heat dissipation problem of the central processing unit (CPU) and the graphics processing unit (GPU) of highest working loads is generally a most sticky problem. Especially, recently, the images of various computer games have become finer and finer and the function of the computer-assisted graphics software has become stronger and stronger. In operation, such kind of software often makes the central processing unit and the graphics processing unit in a high-load state and leads to generation of a great amount of heat. In case the heat is not efficiently dissipated, the performance of the central processing unit or the graphics processing unit will be deteriorated or even the central processing unit or the graphics processing unit will be damaged or the lifetime of the central processing unit or the graphics processing unit will be shortened in some more serious cases.

It is therefore tried by the applicant to provide a heat dissipation structure of electronic device with high heat dissipation efficiency to solve the above problem.

### SUMMARY OF THE INVENTION

It is therefore a primary object of the present invention to provide a heat dissipation structure of electronic device, which can create at least two airflows flowing in different directions to help in dissipating the heat.

It is a further object of the present invention to provide a heat dissipation structure of electronic device, which can create at least two airflows flowing in different directions to help in dissipating the heat.

It is still a further object of the present invention to provide a heat dissipation structure of electronic device, in which the main body has perpendicular and L-shaped heat pipes. The heat pipes are arranged in rows or lines to intersect each other and/or arranged in rows or lines in parallel to each other.

To achieve the above and other objects, the heat dissipation structure of electronic device of the present invention includes: a main body having a first heat pipe set and a second heat pipe set, the first heat pipe set including at least one first heat pipe normal to the main body, a first thermal module being disposed on the first heat pipe, the second heat pipe set including at least one second heat pipe having a first section normal to the main body and a second section bent and extending from the first section in parallel to the main body, a second thermal module being disposed on the second section of the second heat pipe; a first fan connected with the first thermal module to create a first airflow flowing in a first direction; and a second fan connected with the second thermal module to create a second airflow flowing in a second direction.

In the above heat dissipation structure of electronic device, the first airflow flows through the first and second thermal modules, while the second airflow flows through the second thermal module to impact the first airflow flowing through the second thermal module.

In the above heat dissipation structure of electronic device, the main body is a vapor chamber or a flat-plate heat pipe. The main body has a main body chamber. A main body capillary structure is disposed in the main body chamber and a working fluid is contained in the main body chamber. The main body is formed with multiple perforations in communication with the main body chamber.

In the above heat dissipation structure of electronic device, the first heat pipe has a first closed end and a first open end and a first heat pipe chamber positioned between the first closed end and the first open end. The first open end passes through the perforation of the main body to connect with the main body, whereby the first heat pipe chamber communicates with the main body chamber through the first open end. The second heat pipe has a second closed end and a second open end and a second heat pipe chamber positioned between the second closed end and the second open end. The second open end passes through the perforation of the main body to connect with the main body, whereby the second heat pipe chamber communicates with the main body chamber through the second open end.

In the above heat dissipation structure of electronic device, a first heat pipe capillary structure is disposed in the first heat pipe chamber in contact with the main body capillary structure and a second heat pipe capillary structure is disposed in the second heat pipe chamber in contact with the main body capillary structure.

In the above heat dissipation structure of electronic device, the first thermal module includes multiple stacked first heat dissipation sheets. The first heat dissipation sheets are arranged at intervals. Each two adjacent first heat dissipation sheets define therebetween a first airflow passage. The second thermal module includes multiple stacked second heat dissipation sheets. The second heat dissipation sheets are arranged at intervals. Each two adjacent second heat dissipation sheets define therebetween a second airflow passage.

In the above heat dissipation structure of electronic device, the first heat dissipation sheets and the second heat dissipation sheets are radiating fins or vapor chambers or heat sinks.

In the above heat dissipation structure of electronic device, the second section of the at least one second heat pipe is positioned above the main body and spaced from the main body.

In the above heat dissipation structure of electronic device, the first heat pipe set further includes at least one third heat pipe. The third heat pipe has a third section normal to the main body and a fourth section bent and extending from the third section in parallel to the main body in contact with the first thermal module.

In the above heat dissipation structure of electronic device, the second heat pipe set further includes at least one fourth heat pipe normal to the main body in contact with the second thermal module.

In the above heat dissipation structure of electronic device, the second heat pipe set further includes at least one fifth heat pipe and at least one sixth heat pipe normal to the main body. A third thermal module is disposed on the fifth heat pipe. A fourth thermal module is disposed on the sixth heat pipe. A third fan is connected with the third thermal module to create a third airflow flowing from the third thermal module to the second thermal module. A fourth fan is connected with the fourth thermal module to create a fourth airflow flowing from the fourth thermal module to the second thermal module.

In the above heat dissipation structure of electronic device, the first direction of the first airflow is parallel to the main body or inclined toward the main body, while the second direction of the second airflow is normal to the main body.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of the present invention;

FIG. 2 is a perspective assembled view of the present invention;

FIG. 3 is a perspective assembled view of the present invention, showing that the main body is assembled with the first fan and the second fan;

FIG. 4A is a view showing the operation of the present invention;

FIG. 4B is a view showing the operation of a modified embodiment of the present invention;

FIG. 5A is a sectional view taken along line 5A-5A of FIG. 1;

FIG. 5B is an enlarged view of circled area of FIG. 5A;

FIG. 6A is a sectional view taken along line 6A-6A of FIG. 1;

FIG. 6B is an enlarged view of circled area of FIG. 6A;

FIG. 7 is a perspective exploded view of a second embodiment of the present invention;

FIG. 8 is a perspective exploded view of a third embodiment of the present invention; and

FIG. 9 is a perspective assembled view of a fourth embodiment of the present invention.

### DETAILED DESCRIPTION OF THE PREFERRED EMBODIMENTS

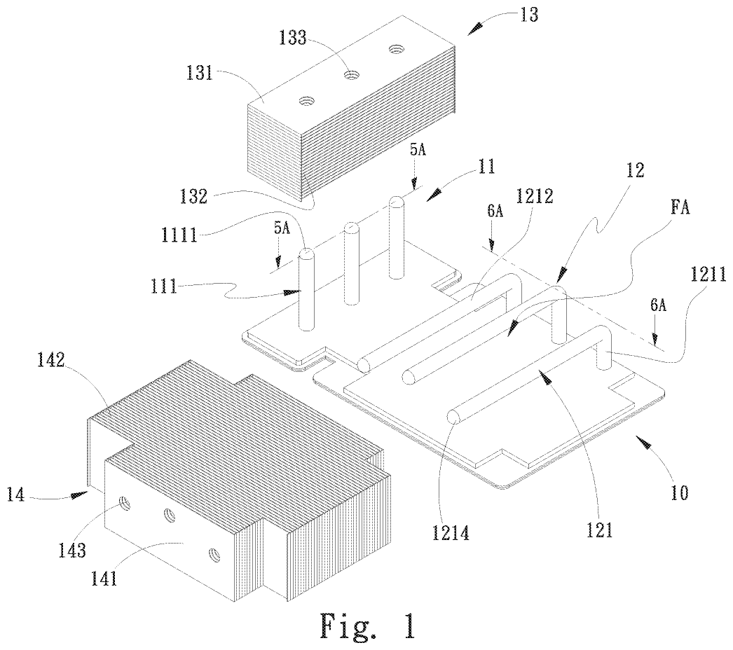

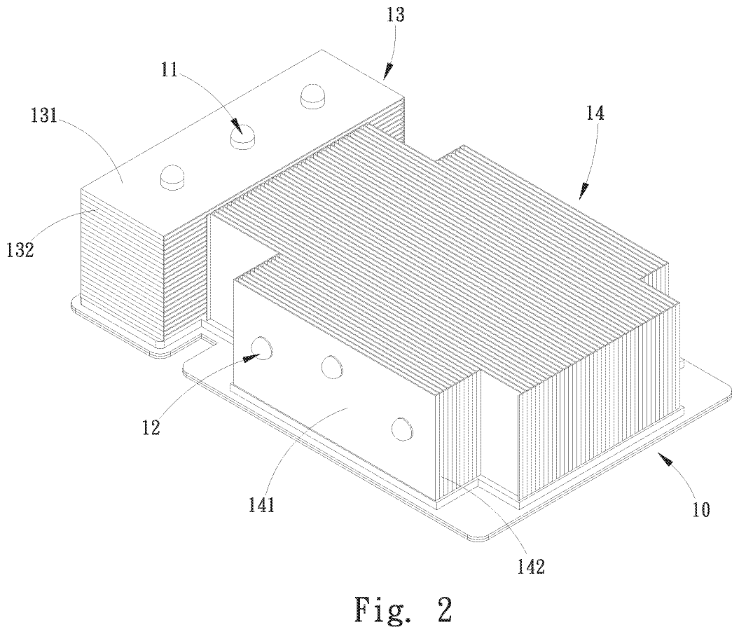

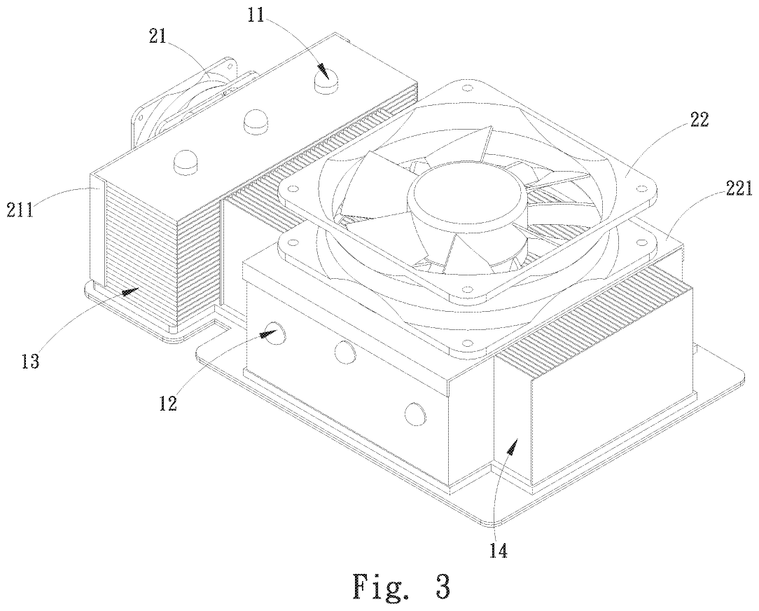

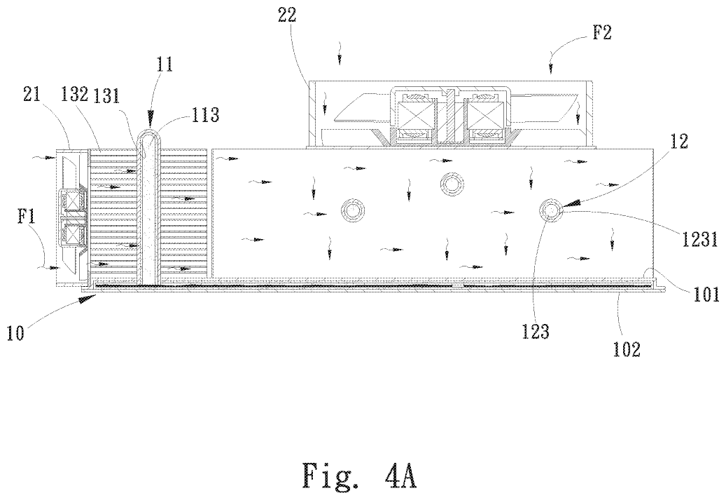

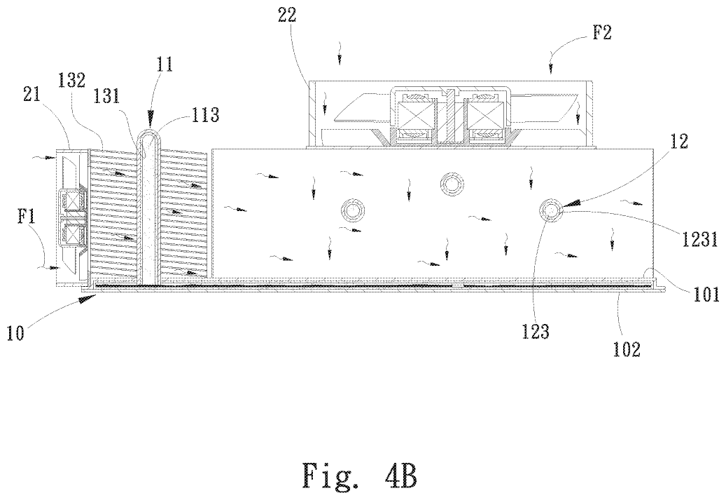

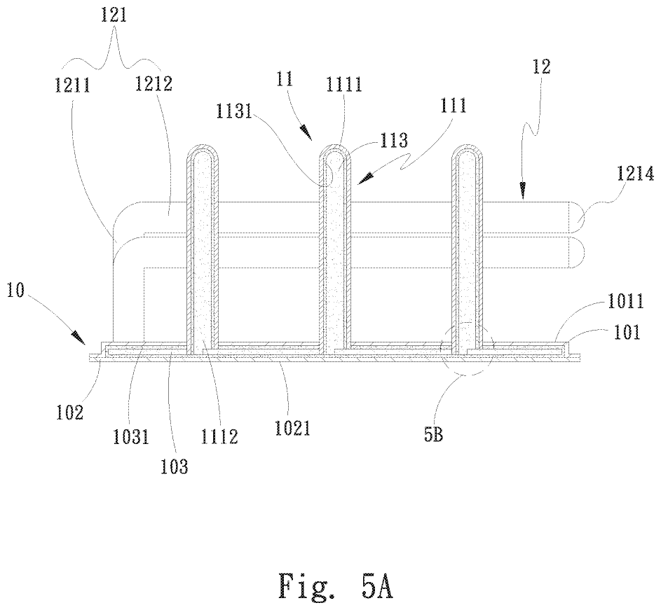

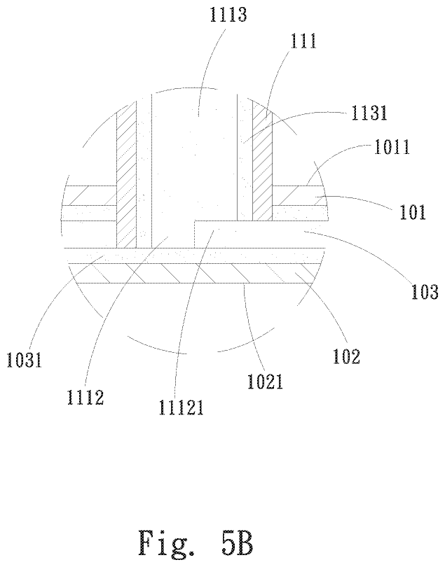

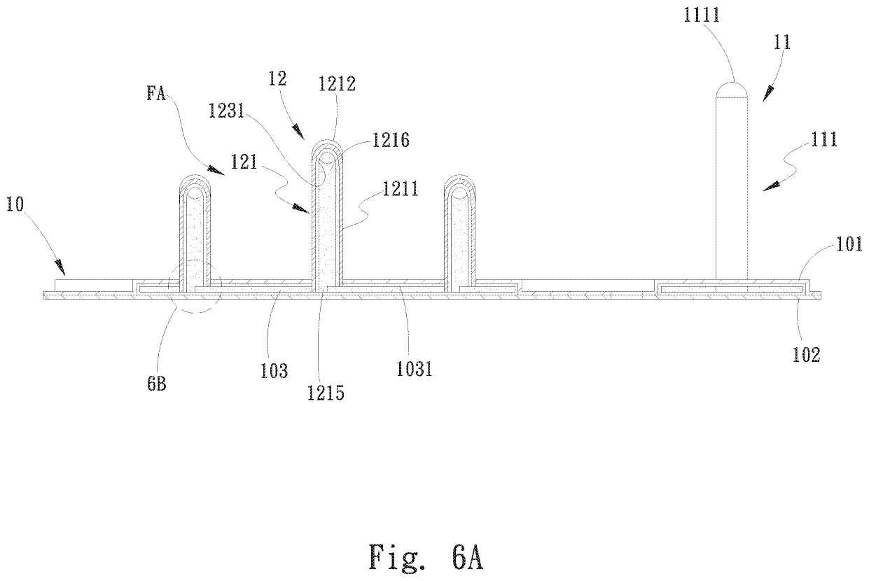

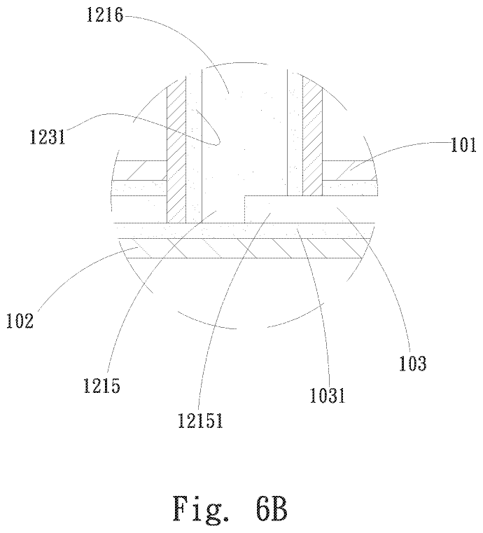

Please refer to FIGS. 1 to 6B. FIG. 1 is a perspective exploded view of the present invention. FIG. 2 is a perspective assembled view of the present invention. FIG. 3 is a perspective assembled view of the present invention, showing that the main body is assembled with the first fan and the second fan. FIG. 4A is a view showing the operation of the present invention. FIG. 4B is a view showing the operation of a modified embodiment of the present invention. FIG. 5A is a sectional view taken along line 5A-5A of FIG. 1. FIG. 5B is an enlarged view of circled area of FIG. 5A. FIG. 6A is a sectional view taken along line 6A-6A of FIG. 1. FIG. 6B is an enlarged view of circled area of FIG. 6A. As shown in the drawings, the heat dissipation structure of electronic device of the present invention includes a main body 10, a first fan 21 and a second fan 22. The main body 10 has a first heat pipe set 11 and a second heat pipe set 12. The main body 10 is such as a vapor chamber or a flat-plate heat pipe. The main body 10 has an upper case 101 and a lower case 102. A main body chamber 103 is defined between the upper and lower cases 101, 102. A lower surface 1021 of the lower case 102 is a heat contact face in contact with at least one heat source. An upper surface 1011 of the upper case 101 is a heat dissipation face. A main body capillary structure 1031 is disposed in the main body chamber 103 and a working fluid is contained in the main body chamber 103 or multiple support columns are disposed in the main body chamber 103 to support the upper and lower cases 101, 102 (as shown in FIGS. 5A, 5B and 6A). Moreover, a multidirectional fluid impact field FA is defined above the main body 10 (such as on the upper side of the upper case 101) to provide a field for the fluid driven by the first and second fans 21, 22 to flow through.

The first and second heat pipe sets 11, 12 are disposed on the upper case 101 of the main body 10. That is, one end of the first heat pipe 11 and one end of the second heat pipe 12 (such as the open end as described hereinafter) are, but not limited to, connected with the upper case 101 of the main body 10. Alternatively, one end (such as the open end) of the first heat pipe 11 and one end (such as the open end) of the second heat pipe 12 are connected with the lateral side of the main body 10. The first heat pipe set 11 includes at least one first heat pipe 111 (there are three in the drawing) normal to the main body 10. The second heat pipe set 12 includes at least one second heat pipe 121 (there are three in the drawing). Each second heat pipe 121 has a first section 1211 normal to the main body 10 and a second section 1212 bent and extending from the first section 1211 in parallel to the main body 10. The second section 1212 is positioned above the main body 10 and spaced from the main body 10. The first and second heat pipe sets 11, 12 are such as circular heat pipes, flat heat pipes, D-shaped heat pipes or flat-plate heat pipes.

Moreover, as shown in FIGS. 5A, 5B, 6A and 6B, the first heat pipe 111 of the first heat pipe set 11 has a first closed end 1111 and a first open end 1112 and a first heat pipe chamber 1113 positioned between the first closed end 1111 and the first open end 1112. The first open end 1112 penetrates through the upper case 101 of the main body 10 and is formed with a communication hole 11121 in communication with the main body chamber 103. Accordingly, the first heat pipe chamber 1113 communicates with the main body chamber 103 through the first open end 1112. A first heat pipe capillary structure 1131 is disposed in the first heat pipe chamber 1113 in contact with the main body capillary structure 1031. The second heat pipe 121 of the second heat pipe set 12 has a second closed end 1214 and a second open end 1215 and a second heat pipe chamber 1216 positioned between the second closed end 1214 and the second open end 1215. The second open end 1215 penetrates through the upper case 101 of the main body 10 and is formed with a communication hole 12151 in communication with the main body chamber 103. Accordingly, the second heat pipe chamber 1216 communicates with the main body chamber 103 through the second open end 1215. A second heat pipe capillary structure 1231 is disposed in the second heat pipe chamber 1216 in contact with the main body capillary structure 1031. Accordingly, the working fluid can vapor-liquid circulate within the main body chamber 103, the first heat pipe chamber 1113 and the second heat pipe chamber 1216 to transfer the heat to the first heat pipe set 11 and the second heat pipe set 12 and the upper surface 1011 of the upper case 101 of the main body 10 to dissipate the heat.

Further referring to FIGS. 1 to 4A and 4B, a first thermal module 13 is fitted with the first heat pipes 111 of the first heat pipe set 11. A second thermal module 14 is fitted with the second heat pipes 121 of the second heat pipe set 12 and positioned in the multidirectional fluid impact field above the main body 10. The first thermal module 13 includes multiple stacked first heat dissipation sheets 131. The first heat dissipation sheets 131 are arranged at intervals. Each two adjacent first heat dissipation sheets 131 define therebetween a first airflow passage 132 in parallel to the main body 10 or inclined toward the main body 10 corresponding to the second thermal module 14. In addition, each first heat dissipation sheet 131 is formed with at least one perforation 133 fitted with the first heat pipe 111. The second thermal module 14 includes multiple stacked second heat dissipation sheets 141. The second heat dissipation sheets 141 are arranged at intervals. Each two adjacent second heat dissipation sheets 141 define therebetween a second airflow passage 142 normal to the main body 10 corresponding to the first thermal module 13. In addition, each second heat dissipation sheet 141 is formed with at least one perforation 143 fitted with the second section 1212 of the second heat pipe 121. Moreover, the first heat dissipation sheets 131 of the first thermal module 13 and the second heat dissipation sheets 141 of the second thermal module 14 are such as heat sinks or radiating fins or vapor chambers. In case of vapor chambers, a chamber is defined in the vapor chamber and a working fluid is contained in the chamber to vapor-liquid circulate within the chamber.

Furthermore, the first fan 21 is directly or indirectly connected with the first thermal module 13. The second fan 22 is directly or indirectly connected with the second thermal module 14. As shown in the drawings, the first and second fans 21, 22 (such as axial flow fans, centrifugal fans or cross flow fans) can be directly respectively connected with the first and second thermal modules 13, 14 or connected with the first and second thermal modules 13, 14 via adapter frames 211, 221. In addition, as shown in FIG. 4A, the first airflow passage 132 is parallel to the main body 10 so that when the first fan 21 operates to create a first airflow F1 passing through the first airflow passage 132, the first airflow F1 flows from the first thermal module 13 to the second thermal module 14 in a first direction (in parallel to the main body 10 as shown in FIG. 4A). In a modified embodiment as shown in FIG. 4B, the first airflow passage 132 is inclined toward the main body 10 so that when the first airflow F1 passes through the first airflow passage 132, the first airflow F1 flows from the first thermal module 13 to the second thermal module 14 in a first direction (inclined toward the main body 10 as shown in FIG. 4B).

Furthermore, when the second fan 22 operates to create a second airflow F2 flowing in a second direction (normal to the main body 10), the second airflow F2 of the second fan 22 flows through the second thermal module 14 to impact the first airflow F1 flowing to the second thermal module 14, whereby the first and second airflows F1, F2 dissipate the heat of the first and second thermal modules 13, 14 by way of thermal convection.

According to the above arrangement, the present invention provides the first and second airflows F1, F2 to flow through the first and second thermal modules 13, 14 in different directions to create thermal convection. In addition, the first and second airflows F1, F2 impact each other in the multidirectional fluid impact field FA above the main body 10 to help in dissipating the heat of the main body 10.

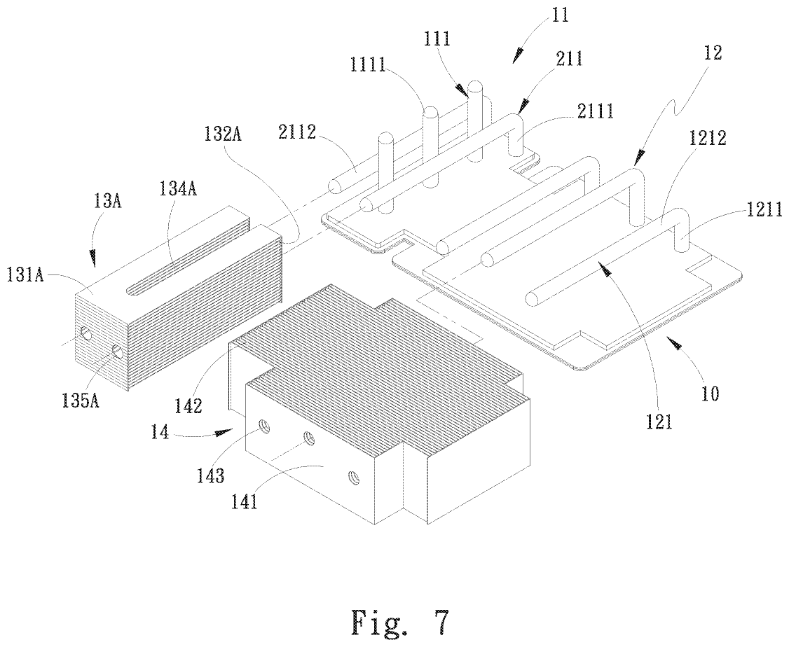

As shown in FIG. 7, in a modified embodiment, the first heat pipe set 11 further includes at least one third heat pipe 211. The third heat pipe 211 has a third section 2111 normal to the main body 10 and a fourth section 2112 bent and extending from the third section 2111 in parallel to the main body 10 in contact with the first thermal module 13A. The third heat pipe 211 is adjacent to the first heat pipes 111. In addition, according to the design requirement, the first and third heat pipes 111, 211 can be arranged in rows or lines to intersect each other and/or arranged in rows or lines in parallel to each other and/or arranged in rows or lines at different heights. The structure of the third heat pipe 211 is substantially identical to the structure of the second heat pipe 121. In addition, in adaptation to the first and third heat pipes 111, 211, the first thermal module 13A is formed with perforations 135A for the fourth sections 2112 of the third heat pipes 211 to pass through and fit with. Also, the first thermal module 13A is formed with a slot 134A corresponding to the first heat pipes 111. The first thermal module 13A includes multiple stacked first heat dissipation sheets 131A. The first heat dissipation sheets 131A are arranged at intervals. Each two adjacent first heat dissipation sheets 131A define therebetween a first airflow passage 132A.

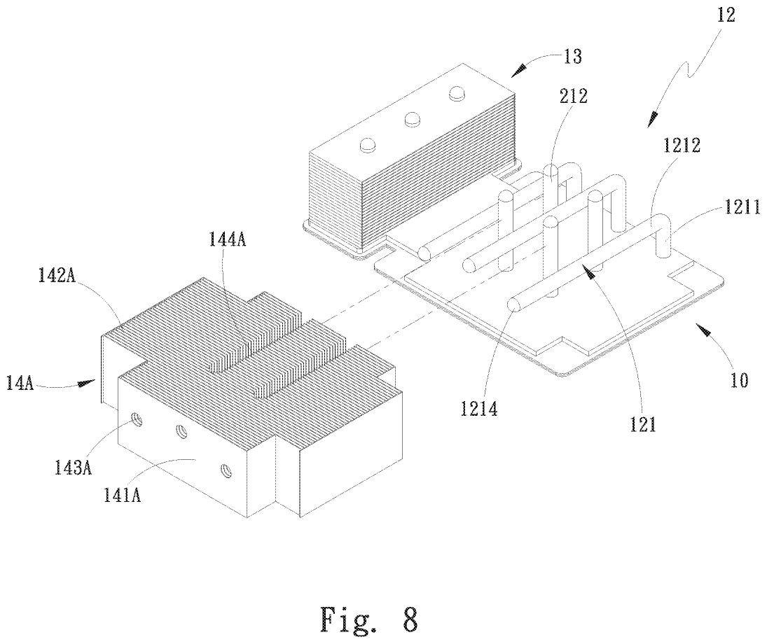

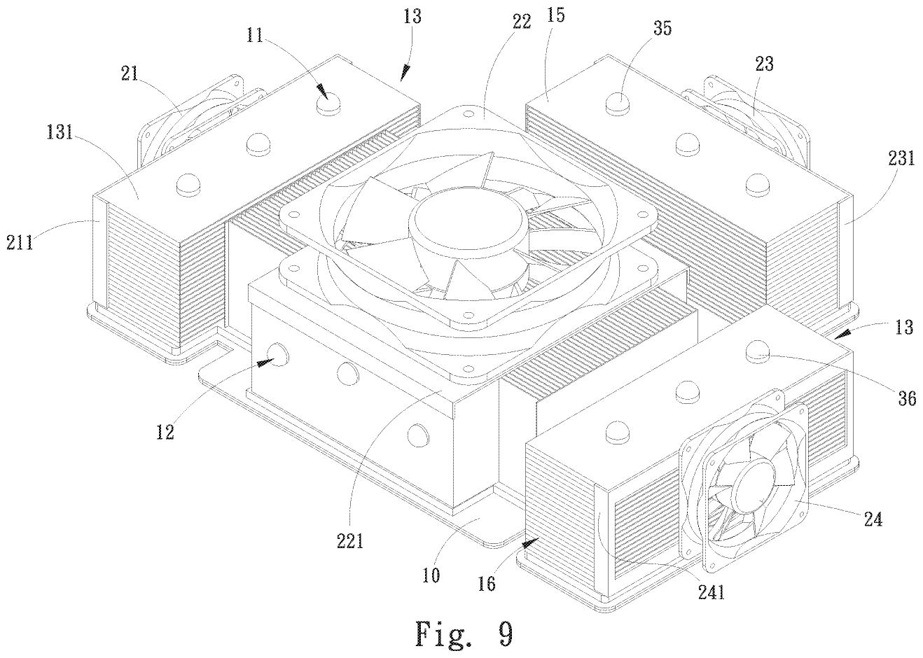

As shown in FIG. 8, in another modified embodiment, the second heat pipe set 12 further includes at least one fourth heat pipe 212 normal to the main body 10 in contact with second thermal module 14A. The fourth heat pipe 212 is adjacent to the second heat pipes 121. In addition, according to the design requirement, the second and fourth heat pipes 121, 212 can be arranged in rows or lines to intersect each other and/or arranged in rows or lines in parallel to each other and/or arranged in rows or lines at different heights (as shown in FIGS. 8 and 9). The structure of the fourth heat pipe 212 is substantially identical to the structure of the first heat pipe 111. In addition, in adaptation to the second and fourth heat pipes 121, 212, the second thermal module 14A is formed with perforations 143A for the second sections 1212 of the second heat pipes 121 to pass through and fit with. Also, the second thermal module 14A is formed with slots 144A corresponding to the fourth heat pipes 212. The second thermal module 14A includes multiple stacked second heat dissipation sheets 141A. The second heat dissipation sheets 141A are arranged at intervals. Each two adjacent second heat dissipation sheets 141A define therebetween a second airflow passage 142A.

As shown in FIG. 9, in still another modified embodiment, the second heat pipe set 12 further includes at least one fifth heat pipe 35 and at least one sixth heat pipe 36 normal to the main body 10. As shown in the drawing, there are three fifth heat pipes 35 and three sixth heat pipes 36. The structures of the fifth and sixth heat pipes 35, 36 are substantially identical to the structure of the first heat pipe 111. A third thermal module 15 and a fourth thermal module 16 are respectively fitted and connected with the fifth and sixth heat pipes 35, 36. The structures of the third and fourth thermal modules 15, 16 are identical to the structure of the first thermal module 13. A third fan 23 is directly or indirectly connected with the third thermal module 15. A fourth fan 24 is directly or indirectly connected with the fourth thermal module 16. As shown in the drawing, the third and fourth fans 23, 24 are such as axial flow fans and respectively connected with the third and fourth thermal modules 15, 16 via adapter frames 231, 241. The third fan 23 operates to create a third airflow flowing from the third thermal module 15 to the second thermal module 14. The fourth fan 24 operates to create a fourth airflow flowing from the fourth thermal module 16 to the second thermal module 14. The first, second, third and fourth airflows impact each other in the multidirectional fluid impact field FA above the main body 10 to help in dissipating the heat of the main body 10.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A heat dissipation structure of electronic device, comprising:
a main body having a first heat pipe set and a second heat pipe set, the first heat pipe set including at least one first heat pipe normal to the main body, a first thermal module being disposed on the first heat pipe, the second heat pipe set including at least one second heat pipe having a first section normal to the main body and a second section bent and extending from the first section in parallel to the main body, a second thermal module being disposed on the second section of the second heat pipe;
a first fan connected with the first thermal module to create a first airflow flowing in a first direction; and
a second fan connected with the second thermal module to create a second airflow flowing in a second direction.

2. The heat dissipation structure of electronic device as claimed in claim 1, wherein the first airflow flows from the first thermal module to the second thermal module, while the second airflow flows through the second thermal module to impact the first airflow flowing to the second thermal module.

3. The heat dissipation structure of electronic device as claimed in claim 1, wherein the main body is a vapor chamber or a flat-plate heat pipe, the main body having a main body chamber, a main body capillary structure being disposed in the main body chamber and a working fluid being contained in the main body chamber.

4. The heat dissipation structure of electronic device as claimed in claim 3, wherein the at least one first heat pipe has a first closed end and a first open end and a first heat pipe chamber positioned between the first closed end and the first open end, the first open end penetrating through the main body in communication with the main body chamber, whereby the first heat pipe chamber communicates with the main body chamber through the first open end, the at least one second heat pipe having a second closed end and a second open end and a second heat pipe chamber positioned between the second closed end and the second open end, the second open end penetrating through the main body in communication with the main body chamber, whereby the second heat pipe chamber communicates with the main body chamber through the second open end.

5. The heat dissipation structure of electronic device as claimed in claim 4, wherein a first heat pipe capillary structure is disposed in the first heat pipe chamber in contact with the main body capillary structure, the first open end being formed with a communication hole in communication with the main body chamber, a second heat pipe capillary structure being disposed in the second heat pipe chamber in contact with the main body capillary structure, the second open end being formed with a communication hole in communication with the main body chamber.

6. The heat dissipation structure of electronic device as claimed in claim 1, wherein the first thermal module includes multiple stacked first heat dissipation sheets, the first heat dissipation sheets being arranged at intervals, each two adjacent first heat dissipation sheets defining therebetween a first airflow passage, the second thermal module including multiple stacked second heat dissipation sheets, the second heat dissipation sheets being arranged at intervals, each two adjacent second heat dissipation sheets defining therebetween a second airflow passage.

7. The heat dissipation structure of electronic device as claimed in claim 6, wherein the first heat dissipation sheets and the second heat dissipation sheets are radiating fins or vapor chambers or heat sinks.

8. The heat dissipation structure of electronic device as claimed in claim 1, wherein the second section of the at least one second heat pipe is positioned above the main body and spaced from the main body.

9. The heat dissipation structure of electronic device as claimed in claim 1, wherein the first heat pipe set further includes at least one third heat pipe, the third heat pipe having a third section normal to the main body and a fourth section bent and extending from the third section in parallel to the main body in contact with the first thermal module.

10. The heat dissipation structure of electronic device as claimed in claim 1, wherein the second heat pipe set further includes at least one fourth heat pipe normal to the main body in contact with the second thermal module.

11. The heat dissipation structure of electronic device as claimed in claim 1, wherein the second heat pipe set further includes at least one fifth heat pipe and at least one sixth heat pipe normal to the main body, a third thermal module being disposed on the fifth heat pipe, a fourth thermal module being disposed on the sixth heat pipe, a third fan being connected with the third thermal module to create a third airflow flowing from the third thermal module to the second thermal module, a fourth fan being connected with the fourth thermal module to create a fourth airflow flowing from the fourth thermal module to the second thermal module.

12. The heat dissipation structure of electronic device as claimed in claim 1, wherein the first direction of the first airflow is parallel to the main body or inclined toward the main body, while the second direction of the second airflow is normal to the main body.

13. The heat dissipation structure of electronic device as claimed in claim 1, wherein a multidirectional fluid impact field is defined above the main body.
